(19) United States
(12) Patent Application Publication
(10) Pub. No.: US 2026/0198353 A1
(43) Pub. Date: Jul. 9, 2026

(54) STACKED PACKAGE STRUCTURE AND METHOD FOR FORMING THE SAME

(71) Applicant: JCET Microelectronics (Jiangyin) Co., LTD., Jiangyin (CN)

(72) Inventor: Cheng YANG, Jiangyin (CN)

(73) Assignee: JCET Microelectronics (Jiangyin) Co., LTD., Jiangyin (CN)

(21) Appl. No.: 19/439,417

(22) Filed: Jan. 4, 2026

(30) Foreign Application Priority Data
Jan. 9, 2025 (CN) 202510036201.5

(51) Int. Cl. H10W 70/67; H10W 70/65; H10W 90/20; H10W 90/26

(52) U.S. Cl. CPC H10W 70/688; H10W 70/65; H10W 90/26; H10W 90/297

(57) ABSTRACT

A stacked package structure and a method for forming the same are provided. The stacked package structure includes: a first substrate including an upper surface and a lower surface; a chip stacked structure located on the upper surface of the first substrate, where the chip stacked structure includes first semiconductor chips; and a flexible circuit board mounted on a side surface of the chip stacked structure, where the flexible circuit board includes a first functional surface and a second functional surface; the first functional surface is close to the corresponding side surface of the chip stacked structure; the second functional surface is away from the corresponding side surface of the chip stacked structure; and second semiconductor chips are mounted on the second functional surface of the flexible circuit board.

### CROSS-REFERENCE TO RELATED APPLICATIONS

This application claims the benefit of priority to Chinese Application No. 202510036201.5, filed on January 9, 2025, which is incorporated herein by reference in its entirety.

### TECHNICAL FIELD

The present disclosure relates to the field of semiconductor package, and particularly relates to a stacked package structure and a method for forming the same.

### BACKGROUND

As chip miniaturization becomes increasingly difficult while the market's pursuit of high-performance chips remains relentless, the industry has begun to explore breakthroughs in the package field, and in recent years, advanced chip package technologies such as 2.5D package technology, 3D package technology, etc., become a focus of attention for foundries, package and testing factories, chip design manufacturers, and EDA manufacturers.

### SUMMARY

An embodiment of the present disclosure provides a stacked package structure, which includes: a first substrate, the first substrate includes opposed upper surface and lower surface; a chip stacked structure located on the upper surface of the first substrate, the chip stacked structure includes a plurality of first semiconductor chips stacked in sequence along a direction perpendicular to the upper surface of the first substrate, the chip stacked structure being electrically connected with the first substrate; and a flexible circuit board mounted on at least one side surface of the chip stacked structure, the flexible circuit board includes opposed first functional surface and second functional surface, the first functional surface being close to the corresponding side surface of the chip stacked structure and perpendicular to the upper surface of the first substrate, the second functional surface being away from the corresponding side surface of the chip stacked structure and perpendicular to the upper surface of the first substrate, and second semiconductor chips electrically connected with the flexible circuit board are mounted on the second functional surface of the flexible circuit board.

In some embodiments, each first semiconductor chip in the chip stacked structure includes opposed first surface and second surface, and a first side surface located between the first surface and the second surface, and the first semiconductor chips include in them integrated circuits, and the first surface has a plurality of discrete first external terminals, and the second surface has a plurality of discrete second external terminals, and the first external terminals and second external terminals are electrically connected with the integrated circuits; when a plurality of first semiconductor chips are stacked in sequence along a direction perpendicular to the upper surface of the first substrate, the first surfaces of the first semiconductor chips in the upper-layer are stacked facing downward on the second surfaces of the first semiconductor chips in the lower-layer, and the first external terminals on the first surfaces of the first semiconductor chips in the upper-layer are electrically connected with the second external terminals on the second surfaces of the first semiconductor chips in the lower-layer; the first substrate has in it first lines, and the upper surface of the first substrate has a plurality of discrete first upper solder pads, and the lower surface of the first substrate has a plurality of discrete first lower solder pads, the first upper solder pads and first lower solder pads are electrically connected with the first lines, the first external terminals on the first surfaces of the first semiconductor chips of the bottommost layer are electrically connected with the corresponding first upper solder pads on the upper surface of the first substrate.

In some embodiments, the first side surfaces of the first semiconductor chips include first side solder pads; the flexible circuit board has in it second lines, and the first functional surface of the flexible circuit board has a plurality of discrete first solder pads, and the second functional surface of the flexible circuit board has a plurality of discrete second solder pads, and the first solder pads and the second solder pads are electrically connected with the second lines; the second semiconductor chips are electrically connected with the corresponding second solder pads on the second functional surface of the flexible circuit board; the first solder pads on the first functional surface of the flexible circuit board are electrically connected with the first side solder pads on the first side surface of the corresponding first semiconductor chips in the chip stacked structure.

In some embodiments, the flexible circuit board is mounted on at least one side surface of the chip stacked structure, and the first solder pads on the first functional surface of the flexible circuit board being electrically connected with the first side solder pads on the first side surface of the corresponding first semiconductor chips in the chip stacked structure includes: the first solder pads on the first functional surface of the flexible circuit board are soldered together with and electrically connected with the first side solder pads on the first side surface of the corresponding first semiconductor chips in the chip stacked structure through first solder bumps; and the second semiconductor chips being electrically connected with the corresponding second solder pads on the second functional surface of the flexible circuit board includes: the second semiconductor chips are electrically connected with the corresponding second solder pads on the second functional surface of the flexible circuit board through second solder bumps.

In some embodiments, the flexible circuit board further includes a plurality of second side surfaces located between the first functional surface and the second functional surface, a second side surface of the flexible circuit board close to the upper surface of the first substrate is suspended above the upper surface of the first substrate or adhered to the upper surface of the first substrate.

In some embodiments, the first side surfaces of the first semiconductor chips do not include first side solder pads; the flexible circuit board has in it second lines, and the first functional surface of the flexible circuit board further has a plurality of discrete first solder pads, and the second functional surface of the flexible circuit board has a plurality of discrete second solder pads, and the first solder pads and the second solder pads are electrically connected with the second lines; the second semiconductor chips are electrically connected with the corresponding second solder pads; and the first functional surface of the flexible circuit board is adhered to the side surface of the chip stacked structure.

In some embodiments, the flexible circuit board is mounted on at least one side surface of the chip stacked structure, and the first functional surface of the flexible circuit board being mounted on the side surface of the chip stacked structure includes: the first functional surface of the flexible circuit board is adhered to the side surface of the chip stacked structure through an adhesive layer.

In some embodiments, the stacked package structure further includes third semiconductor chips, and the third semiconductor chips are mounted on the first functional surface of the flexible circuit board and electrically connected with corresponding first solder pads on the first functional surface through third solder bumps; the flexible circuit board being mounted on at least one side surface of the chip stacked structure, and the first functional surface of the flexible circuit board being adhered to the side surface of the chip stacked structure includes: the third semiconductor chips mounted on the first functional surface of the flexible circuit board are adhered to the side surface of the chip stacked structure through an adhesive layer.

In some embodiments, the flexible circuit board is electrically connected with the first substrate.

In some embodiments, the flexible circuit board being electrically connected with the first substrate includes: a part of the flexible circuit board is bent and extends parallel to a part of the upper surface of the first substrate, the bent portion of the flexible circuit board is soldered and electrically connected with the corresponding first upper solder pads on the upper surface of the first substrate through connection solder balls.

In some embodiments, the flexible circuit board being electrically connected with the first substrate includes: the flexible circuit board and the first substrate are rigid-flex boards, the flexible circuit board is flexible and the first substrate is rigid, and the flexible circuit board is partially embedded into the first substrate and electrically connected with the first substrate.

In some embodiments, the flexible circuit board being electrically connected with the first substrate includes: the first substrate further includes a plurality of side surfaces located between the upper surface and the lower surface, the flexible circuit board extends from at least one side surface of the first substrate to the lower surface of the first substrate and is electrically connected with the first substrate from the lower surface of the first substrate.

In some embodiments, the flexible circuit board being electrically connected with the first substrate includes: the first substrate is also a flexible board, the first substrate and the flexible circuit board are a one-piece structure with an electrical connection, and the flexible circuit board is bent upward from at least one side of the first substrate.

In some embodiments, the surfaces of the first lower solder pads on the lower surface of the first substrate include protruding first external solder bumps; the stacked package structure further includes: a second substrate, and the second substrate has in it third lines, and the upper surface of the second substrate has second upper solder pads, and the lower surface of the second substrate has second lower solder pads, and the second upper solder pads and second lower solder pads are electrically connected with the third lines; the first substrate is located on the second substrate, and the first external solder bumps on the lower surface of the first substrate are soldered together with the corresponding second upper solder pads on the upper surface of the second substrate; the surfaces of the second lower solder pads on the lower surface of the second substrate include protruding second external solder bumps.

In some embodiments, a part of the flexible circuit board is bent and extends parallel to the second surfaces of the first semiconductor chips of the topmost layer in the chip stacked structure, and is electrically connected with a part of the second external terminals on the second surfaces of the first semiconductor chips of the topmost layer.

In some embodiments, the flexible circuit board is located on the upper surface of the first substrate on one or more sides of the chip stacked structure.

In some embodiments, the number of the second semiconductor chips is one or more; when the number of the second semiconductor chips is multiple, the multiple second semiconductor chips are stacked in sequence along a direction parallel to the upper surface of the first substrate on the second functional surface of the flexible circuit board, or the multiple second semiconductor chips are all mounted at different positions on the second functional surface of the flexible circuit board.

In some embodiments, the second semiconductor chips include opposed third surface and fourth surface and a plurality of side surfaces between the third surface and the fourth surface, and the third surface has third external terminals, and the third external terminals on the third surfaces of the second semiconductor chips are electrically connected with the corresponding second solder pads on the second functional surface of the flexible circuit board through second solder bumps; a side surface of the second semiconductor chips close to the upper surface of the first substrate has second side solder pads, and the second side solder pads are soldered together with the corresponding first upper solder pads on the upper surface of the first substrate through fourth solder bumps.

Another embodiment of the present disclosure further provides a method for forming a stacked package structure, which includes: providing a first substrate, the first substrate includes opposed upper surface and lower surface; forming a chip stacked structure on the upper surface of the first substrate, the chip stacked structure includes a plurality of first semiconductor chips stacked in sequence along a direction perpendicular to the upper surface of the first substrate, and the chip stacked structure is electrically connected with the first substrate; and mounting a flexible circuit board on at least one side surface of the chip stacked structure, the flexible circuit board includes opposed first functional surface and second functional surface, and the first functional surface is close to the corresponding side surface of the chip stacked structure and is perpendicular to the upper surface of the first substrate, the second functional surface is away from the corresponding side surface of the chip stacked structure and is perpendicular to the upper surface of the first substrate, and second semiconductor chips electrically connected with the flexible circuit board are mounted on the second functional surface of the flexible circuit board.

In some embodiments, each first semiconductor chip in the chip stacked structure includes opposed first surface and second surface, and a first side surface located between the first surface and the second surface, and the first semiconductor chips include in them integrated circuits, and the first surface has a plurality of discrete first external terminals, and the second surface has a plurality of discrete second external terminals, and the first external terminals and second external terminals are electrically connected with the integrated circuits; when a plurality of first semiconductor chips are stacked in sequence along a direction perpendicular to the upper surface of the first substrate, the first surfaces of the first semiconductor chips in the upper-layer are stacked facing downward on the second surfaces of the first semiconductor chips in the lower-layer, and the first external terminals on the first surfaces of the first semiconductor chips in the upper-layer are electrically connected with the second external terminals on the second surfaces of the first semiconductor chips in the lower-layer; the first substrate has in it first lines, and the upper surface of the first substrate has a plurality of discrete first upper solder pads, and the lower surface of the first substrate has a plurality of discrete first lower solder pads, the first upper solder pads and first lower solder pads are electrically connected with the first lines, the first external terminals on the first surfaces of the first semiconductor chips of the bottommost layer are electrically connected with the corresponding first upper solder pads on the upper surface of the first substrate.

In some embodiments, the first side surfaces of the first semiconductor chips include first side solder pads; the flexible circuit board has in it second lines, and the first functional surface of the flexible circuit board has a plurality of discrete first solder pads, and the second functional surface of the flexible circuit board has a plurality of discrete second solder pads, and the first solder pads and the second solder pads are electrically connected with the second lines; the second semiconductor chips are electrically connected with the corresponding second solder pads on the second functional surface of the flexible circuit board; the first solder pads on the first functional surface of the flexible circuit board are electrically connected with the first side solder pads on the first side surface of the corresponding first semiconductor chips in the chip stacked structure.

In some embodiments, the flexible circuit board is mounted on at least one side surface of the chip stacked structure, and the first solder pads on the first functional surface of the flexible circuit board being electrically connected with the first side solder pads on the first side surface of the corresponding first semiconductor chips in the chip stacked structure includes: the first solder pads on the first functional surface of the flexible circuit board are soldered together with and electrically connected with the first side solder pads on the first side surface of the corresponding first semiconductor chips in the chip stacked structure through first solder bumps; and the second semiconductor chips being electrically connected with the corresponding second solder pads on the second functional surface of the flexible circuit board includes: the second semiconductor chips are electrically connected with the corresponding second solder pads on the second functional surface of the flexible circuit board through second solder bumps.

In some embodiments, the first side surfaces of the first semiconductor chips do not include first side solder pads; the flexible circuit board has in it second lines, and the first functional surface of the flexible circuit board further has a plurality of discrete first solder pads, and the second functional surface of the flexible circuit board has a plurality of discrete second solder pads, and the first solder pads and the second solder pads are electrically connected with the second lines; the second semiconductor chips are electrically connected with the corresponding second solder pads; and the flexible circuit board being mounted on at least one side surface of the chip stacked structure includes: the first functional surface of the flexible circuit board is adhered to the side surface of the chip stacked structure.

In some embodiments, the first functional surface of the flexible circuit board being adhered to the side surface of the chip stacked structure includes: the first functional surface of the flexible circuit board is adhered to the side surface of the chip stacked structure through an adhesive layer.

In some embodiments, the stacked package structure further includes third semiconductor chips, and the third semiconductor chips are mounted on the first functional surface of the flexible circuit board and electrically connected with corresponding first solder pads on the first functional surface through third solder bumps; and the first functional surface of the flexible circuit board being adhered to the side surface of the chip stacked structure includes: the third semiconductor chips mounted on the first functional surface of the flexible circuit board are adhered to the side surface of the chip stacked structure through an adhesive layer.

In some embodiments, the flexible circuit board is electrically connected with the first substrate.

### BRIEF DESCRIPTION OF THE DRAWINGS

In order to facilitate understanding and illustrating the features and advantages of the present disclosure, the components in the following accompanying drawings are not necessarily drawn to scale, and components having similar related characteristics or features may include the same or similar reference numerals.

FIG. 1 is a top view structural schematic diagram of a stacked package structure according to an embodiment of the present disclosure;

FIG. 2 is a cross-sectional structural schematic diagram of the stacked package structure obtained along cutting line AA1 in FIG. 1 according to an embodiment of the present disclosure;

FIG. 3 is a cross-sectional structural schematic diagram of the stacked package structure obtained along cutting line AA1 in FIG. 1 according to another embodiment of the present disclosure;

FIG. 4 is a cross-sectional structural schematic diagram of the stacked package structure obtained along cutting line AA1 in FIG. 1 according to yet another embodiment of the present disclosure;

FIG. 5 is a cross-sectional structural schematic diagram of the stacked package structure obtained along cutting line AA1 in FIG. 1 according to yet another embodiment of the present disclosure;

FIG. 6 is a cross-sectional structural schematic diagram of the stacked package structure obtained along cutting line AA1 in FIG. 1 according to yet another embodiment of the present disclosure;

FIG. 7 is a cross-sectional structural schematic diagram of the stacked package structure obtained along cutting line AA1 in FIG. 1 according to yet another embodiment of the present disclosure;

FIG. 8 is a cross-sectional structural schematic diagram of the stacked package structure obtained along cutting line AA1 in FIG. 1 according to yet another embodiment of the present disclosure;

FIG. 9 is a cross-sectional structural schematic diagram of the stacked package structure obtained along cutting line AA1 in FIG. 1 according to yet another embodiment of the present disclosure;

FIG. 10 is a cross-sectional structural schematic diagram of the stacked package structure obtained along cutting line AA1 in FIG. 1 according to yet another embodiment of the present disclosure;

FIG. 11 is a cross-sectional structural schematic diagram of the stacked package structure obtained along cutting line AA1 in FIG. 1 according to yet another embodiment of the present disclosure;

FIG. 12 is a top view structural schematic diagram of the stacked package structure according to another embodiment of the present disclosure;

FIG. 13 is a cross-sectional structural schematic diagram of the stacked package structure obtained along cutting line AA1 in FIG. 12 according to an embodiment of the present disclosure;

FIG. 14 is a cross-sectional structural schematic diagram of the stacked package structure obtained along cutting line AA1 in FIG. 12 according to another embodiment of the present disclosure;

FIG. 15 is a cross-sectional structural schematic diagram of the stacked package structure obtained along cutting line AA1 in FIG. 12 according to another embodiment of the present disclosure; and

FIG. 16 is a cross-sectional structural schematic diagram of the stacked package structure obtained along cutting line AA1 in FIG. 12 according to another embodiment of the present disclosure.

### DETAILED DESCRIPTION

The specific implementation of the package structure and the method for forming the same provided by the present disclosure are described in detail below in conjunction with the accompanying drawings.

One aspect of the present disclosure provides a stacked package structure, and the stacked package structure of the present disclosure is described in detail below in some embodiments in conjunction with the accompanying drawings.

As chip miniaturization becomes increasingly difficult while the market's pursuit of high-performance chips remains relentless, the industry has begun to explore breakthroughs in the package field, and in recent years, advanced chip package technologies such as 2.5D package technology, 3D package technology, etc., become a focus of attention for foundries, package and testing factories, chip design manufacturers, and EDA manufacturers.

2.5D package technology or 3D package technology is the process of stacking identical or different chips together to form a stacked package structure. The main advantages of 2.5D package technology and 3Dpackage technology include: by sequentially stacking a plurality of chips together along a direction perpendicular to the surface of the substrate to form a chip stacked structure, the integration degree and performance of the chips is thus improved; the connections between a plurality of chips in the chip stacked structure are achieved through vertical connection instead of traditional planar connection methods, so that the total wiring length between the chips can be reduced to increase bandwidth and improve signal latency, and thus enhance the reliability and stability of the package structure.

In stacked package structures formed using 2.5D package technology or 3D package technology, in addition to forming a chip stacked structure on the substrate, other chips (such as control chips, CPU chips, or GPUchips) are also mounted on the surface of the substrate on one side or around the chip stacked structure to improve the performance of the stacked package structure; however, existing other chips are mounted with their active surfaces parallel to the surface of the substrate, which will occupy a large surface area of substrate when other chips are mounted, thereby limiting the number of chips mounted on the surface of the substrate and limiting further improvement of the functionality and performance of the package structure.

The advantages of the technical solution of the present disclosure lie in the following. In the stacked package structure of the present disclosure, since the flexible circuit board is mounted on at least one side surface of the chip stacked structure, while the second semiconductor chips are mounted on the second functional surface of the flexible circuit board away from the corresponding side surface of the chip stacked structure, that is, compared to the existing method of mounting devices in a direction parallel to the upper surface of the first substrate, both the flexible circuit board and the second semiconductor chips in the present disclosure are mounted in a direction perpendicular to the upper surface of the first substrate, so that the area occupied by the flexible circuit board and the second semiconductor chips on the upper surface of the first substrate will be reduced, and thus more other chips or devices can be mounted on the upper surface of the first substrate, so that the functionality and performance of the package structure are further improved.

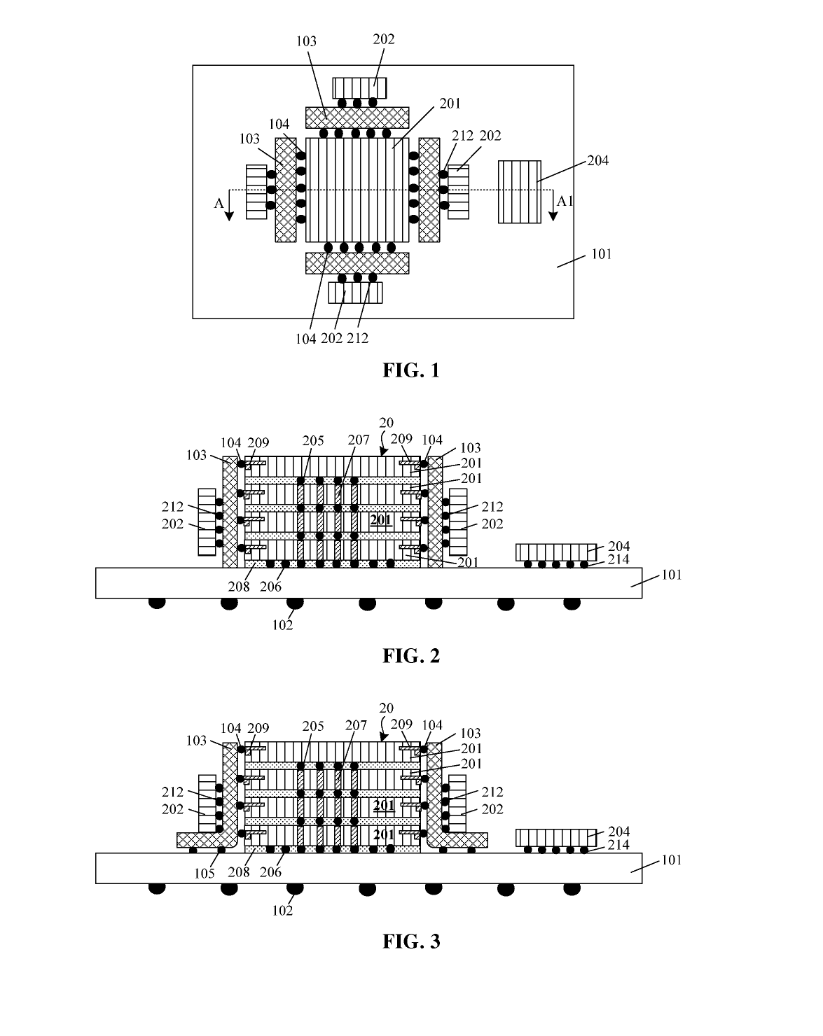

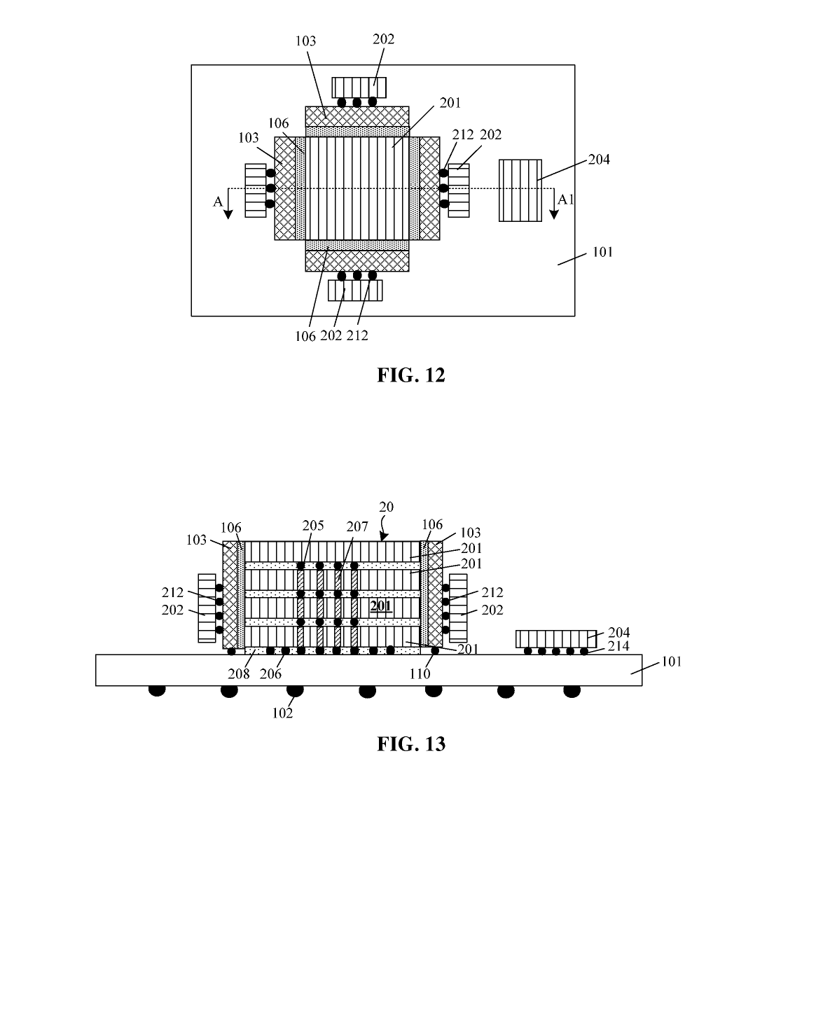

FIG. 1 is a top view structural schematic diagram of a stacked package structure according to an embodiment of the present disclosure; FIG. 2 is a cross-sectional structural schematic diagram of the stacked package structure obtained along cutting line AA1 in FIG. 1 according to an embodiment of the present disclosure. FIG. 12 is a top view structural schematic diagram of the stacked package structure according to another embodiment of the present disclosure; FIG. 13 is a cross-sectional structural schematic diagram of the stacked package structure obtained along cutting line AA1 in FIG. 12 according to an embodiment of the present disclosure.

Referring to FIGS. 1 and 2 or referring to FIGS. 12 and 13, the stacked package structure includes: a first substrate 101, the first substrate 101 includes opposed upper surface and lower surface; a chip stacked structure 20 located on the upper surface of the first substrate 101, the chip stacked structure 20 includes a plurality of first semiconductor chips 201 stacked in sequence along a direction perpendicular to the upper surface of the first substrate 101, and the chip stacked structure 20 is electrically connected with the first substrate 101; and a flexible circuit board 103 mounted on at least one side surface of the chip stacked structure 20, the flexible circuit board 103 includes opposed first functional surface and second functional surface, and the first functional surface is close to the corresponding side surface of the chip stacked structure 20 and perpendicular to the upper surface of the first substrate 101, and the second functional surface is away from the corresponding side surface of the chip stacked structure 20 and perpendicular to the upper surface of the first substrate 101, and second semiconductor chips 202 electrically connected with the flexible circuit board 103 are mounted on the second functional surface of the flexible circuit board 103.

In some embodiments, the first substrate 101 in the stacked package structure serves as a support carrier and connection carrier during the package process. In one embodiment, the first substrate 101 may include opposed upper surface and lower surface, and the upper surface of the first substrate 101 has a plurality of discrete first upper solder pads (i.e., pads on the upper surface of the first substrate 101 facing the chip stacked structure 20), and the lower surface of the first substrate 101 has a plurality of discrete first lower solder pads (i.e., pads on the lower surface of the first substrate 101 facing opposite to the chip stacked structure 20), and the first substrate 101 has in it first lines (i.e., lines formed on the surfaces of the first substrate 101 or in the first substrate 101), a part of the first lines may be used for electrical connection of the first upper solder pads on the upper surface of the first substrate 101 with the corresponding first lower solder pads on the lower surface of the first substrate 101, and a part of the first lines may also be used for electrical connection between a part of the first upper solder pads on the upper surface of the first substrate 101, and a part of the first lines may also be used for electrical connection between a part of the first lower solder pads on the lower surface of the first substrate 101. The first upper solder pads on the upper surface of the first substrate 101 may be electrically connected with the chip stacked structure or other devices mounted on the first substrate, and first external solder bumps 102 may be formed on the first lower solder pads on the lower surface of the first substrate 101, and the first external solder bumps 102 serve to be connected with other devices, other first substrates, or package structures. The materials of the first upper solder pads, the first lower solder pads, and the first lines are metal, which may be one or more of aluminum, copper, nickel, tin, titanium, tungsten, platinum, chromium, tantalum, gold, or silver. The material of the first external solder bumps 102 is tin or tin alloy, and the tin alloy is one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony.

The chip stacked structure 20 in the stacked package structure includes a plurality of first semiconductor chips 201 stacked in sequence along a direction perpendicular to the upper surface of the first substrate 101, and the number of the first semiconductor chips 201 may be two, three, four, or more. In FIG. 2 (or FIG. 13), an explanation is provided by taking the case where the chip stacked structure 20 has in it four first semiconductor chips 201 as an example.

The functions of the plurality of first semiconductor chips 201 in the chip stacked structure 20 are the same or different. In one embodiment, when the functions of the plurality of first semiconductor chips 201 are the same, the internal structures of the plurality of first semiconductor chips 201 are the same. In another embodiment, when the functions of the plurality of first semiconductor chips 201 are the same, the internal structures of the plurality of first semiconductor chips 201 are different.

According to different functions, the first semiconductor chips 201 may include logic chips and/or memory chips. In one embodiment, the logic chips may include but are not limited to gate arrays, unit substrate arrays, embedded arrays, structured application specific integrated circuits (ASICs), field programmable gate arrays (FPGAs), complex programmable logic devices (CPLDs), graphics processing units (GPUs), central processing units (CPUs), microprocessing units (MPUs), microcontroller units (MCUs), logic integrated circuits (ICs), application processors (APs), display driver ICs (DDIs), radio frequency (RF) chips, power chips, or complementary metal oxide semiconductor (CMOS) image sensor. In one embodiment, the memory chips may include but are not limited to dynamic random access memories (DRAMs), static random-access memories (SRAMs), magnetoresistive random access memories (MRAMs), phase-change memories (PRAMs), resistive random access memories (RRAMs), or non-volatile memory chips (e.g., Flash).

In one embodiment, the functions of all first semiconductor chips 201 in the chip stacked structure 20 are the same. In a specific embodiment, all first semiconductor chips 201 in the chip stacked structure 20 are memory chips, for example, all the four first semiconductor chips 201 in the chip stacked structure 20 shown in FIG. 2 (or FIG. 13) are memory chips. In another specific embodiment, all the first semiconductor chips 201 in the chip stacked structure 20 may also be logic chips.

In another embodiment, the functions of a part of the first semiconductor chips 201 in the chip stacked structure 20 are different from the functions of other part of the first semiconductor chips 201. In a specific embodiment, one or two first semiconductor chips 201 located at the bottom layer of the chip stacked structure 20 are logic chips, and the other first semiconductor chips 201 located at the upper layer in the chip stack structure 20 are memory chips, and the logic chips are used to control and manage the data storage process, reading process (and deletion process) of the memory chips, for example, in FIG. 1 (or FIG. 13), a first semiconductor chips 201 at the bottom layer in the chip stacked structure 20 is a logic chip, and three first semiconductor chips 201 located at the upper layer are memory chips.

There are electrical connections between the first semiconductor chips 201 in the upper layer and the first semiconductor chips 201 in the lower layer in the chip stacked structure 20, and there is an electrical connection between a first semiconductor chip 201 in the bottommost layer in the chip stacked structure 20 and the first substrate 101. In one embodiment, each first semiconductor chip 201 in the chip stacked structure includes opposed first surface and second surface, and a first side surface between the first surface and the second surface, and the first semiconductor chips 201 include in them integrated circuits (i.e., circuits formed on or embedded in the first semiconductor chips 201), the integrated circuits may be memory circuits or logic control circuits, and the first surface has a plurality of discrete first external terminals, and the first external terminals may be solder balls 205 or solder balls 206 protruding from the first surface, and the second surface has a plurality of discrete second external terminals, and the second external terminals may be through-via connection structures 207 (e.g., through-silicon-vias, TSVs) exposed on the second surface, and the first external terminals and the second external terminals are electrically connected with the integrated circuits; when the plurality of first semiconductor chips 201 are stacked in sequence along a direction perpendicular to the upper surface of the first substrate, the first surfaces of the first semiconductor chips 201 in the upper layer are stacked facing downward on the second surface of the lower first semiconductor chips 201, and the first external terminals on the first surfaces of the first semiconductor chips 201 in the upper layer are electrically connected with the second external terminals on the second surfaces of the first semiconductor chips 201 in the lower layer, in some embodiments, the solder balls 205 on the first surfaces of the first semiconductor chips 201 in the upper layer are electrically connected with the through-via connection structures 207 exposed on the second surfaces of the first semiconductor chips 201 in the lower layer, and the solder balls 206 (i.e., the first external terminals) on the first surface of a first semiconductor chip 201 at the bottommost layer in the chip stacked structure 20 are electrically connected with the corresponding first upper solder pads on the upper surface of the first substrate 101, and the solder balls 205 are small-sized micro solder balls, and the solder balls 206 may be relatively larger C4 solder balls. It should be noted that in one embodiment, the first semiconductor chips 201 of the topmost layer in the chip stacked structure 20 may not include through-via connection structures 207 (e.g., through-silicon-via connection structure, TSV).

A flexible circuit board 103 is mounted on at least one side surface of the chip stacked structure 20 in the stacked package structure, and the flexible circuit board 103 includes opposed first functional surface and second functional surface, and the first functional surface is close to the corresponding side surface of the chip stacked structure 20 and perpendicular to the upper surface of the first substrate 101, and the second functional surface is away from the corresponding side surface of the chip stacked structure 20 and perpendicular to the upper surface of the first substrate 101, and second semiconductor chips 202, which are electrically connected with the flexible circuit board 103, are mounted on the second functional surface of the flexible circuit board 103. Since the flexible circuit board 103 is mounted on at least one side surface of the chip stacked structure 20, while the second semiconductor chips 202 are mounted on the second functional surface of the flexible circuit board 103 away from the corresponding side surface of the chip stacked structure 20, that is, compared to the existing method of mounting devices in a direction parallel to the upper surface of the first substrate 101, both the flexible circuit board 103 and the second semiconductor chips 202 in the present disclosure are mounted in a direction perpendicular to the upper surface of the first substrate 101, so that the area occupied by the flexible circuit board 103 and the second semiconductor chips 202 on the upper surface of the first substrate 101 will be reduced, and thus more other chips or devices can be mounted on the upper surface of the first substrate 101, so that the functionality and performance of the package structure are further improved.

The flexible circuit board 103 is also known as a soft board or FPC (Flexible Printed Circuit). In one embodiment, the flexible circuit board 103 has in it second lines (i.e., lines formed on the surfaces of the flexible circuit board 103 or in the flexible circuit board 103), and the first functional surface of the flexible circuit board 103 has a plurality of discrete first solder pads, and the second functional surface of the flexible circuit board 103 has a plurality of discrete second solder pads, and the first solder pads and the second solder pads are electrically connected with the second lines.

The chip stacked structure 20 may include a plurality of side surfaces, and the flexible circuit board 103 being mounted on at least one side surface of the chip stacked structure 20 includes: the flexible circuit board 103 is mounted on one of the side surfaces of the chip stacked structure 20, or the flexible circuit board 103 is mounted on two or more side surfaces of the chip stacked structure 20. In one embodiment, the chip stacked structure 20 is a cubic structure, and the chip stacked structure 20 may include a top surface and a bottom surface, as well as four side surfaces located between the top surface and the bottom surface, and the flexible circuit board 103 being mounted on at least one side surface of the chip stacked structure 20 may include: the flexible circuit board 103 is mounted on only one of the side surfaces of the chip stacked structure 20, or the flexible circuit board 103 is mounted on two adjacent or non-adjacent side surfaces of the chip stacked structure 20, or the flexible circuit board 103 is mounted on three of the side surfaces of the chip stacked structure 20, or the flexible circuit board 103 is mounted on four side surfaces of the chip stacked structure 20. In one embodiment, when the flexible circuit board 103 is mounted on two or more side surfaces of the chip stacked structure 20, the flexible circuit board 103 may be multiple, and in some cases, a flexible circuit board 103 may also be bent and then mounted on a plurality of side surfaces of the chip stacked structure 20.

The second semiconductor chips 202 mounted on the second functional surface of the flexible circuit board 103 and electrically connected with the flexible circuit board 103 may include different functions from the first semiconductor chips 201 in the chip stacked structure 20, or may also include the same functions. In one embodiment, the second semiconductor chips 202 may be logic chips or memory chips. In one embodiment, the second semiconductor chips 202 being electrically connected with the flexible circuit board 103 includes: the second semiconductor chips 202 are electrically connected with the corresponding second solder pads on the second functional surface of the flexible circuit board 103, and in some embodiments, the second semiconductor chips 202 may be electrically connected with the corresponding second solder pads on the second functional surface of the flexible circuit board 103 through the second solder bumps 212, and the material of the second solder bumps 212 may be tin or tin alloy.

When the flexible circuit board 103 is mounted on at least one side surface of the chip stacked structure 20, there may be various different methods of electrical connection between the flexible circuit board 103 and the chip stacked structure 20 as well as the first substrate 101 to meet different connection requirements and functional requirements of the stacked package structure, so as to further improve the performance of the stacked package structure. In one embodiment, the flexible circuit board 103 is directly electrically connected with the first semiconductor chips 201 in the chip stacked structure 20, and is directly electrically connected with or is not directly electrically connected with the first substrate 101. In another embodiment, the flexible circuit board 103 is not directly electrically connected with the first semiconductor chips 201 in the chip stacked structure 20, but is directly electrically connected with the first substrate 101. In different embodiments below, when the flexible circuit board 103 is mounted on at least one side surface of the chip stacked structure 20, there may be various specific methods of electrical connection between the flexible circuit board 103 and the chip stacked structure 20 as well as the first substrate 101, which are described in detail.

When the flexible circuit board 103 is directly electrically connected with the first semiconductor chips 201 in the chip stacked structure 20 and is not directly connected with the first substrate 101, in one embodiment, referring again to FIGS. 1 and 2, the first side of the first semiconductor chips 201 in the chip stacked structure 20 has first side solder pads 209, and the second side solder pads 209 are electrically connected with the integrated circuits in the first semiconductor chips 201, and the material of the first side solder pads 209 is metal, and the first side solder pads 209 may be manufactured when the first semiconductor chips 201 are manufactured (e.g., when the internal wirings of the first semiconductor chips 201 are manufactured); the flexible circuit board 103 being directly electrically connected with the first semiconductor chips 201 in the chip stacked structure 20 includes: the first solder pads on the first functional surface of the flexible circuit board 103 are electrically connected with the first side solder pads 209 on the first side surface of the corresponding first semiconductor chips 201 in the chip stacked structure 20, and in some embodiments, the first solder pads on the first functional surface of the flexible circuit board 103 are soldered and electrically connected with the first side solder pads 209 on the first side surface of the corresponding first semiconductor chips 201 in the chip stacked structure 20 through first solder bumps 104, and the material of the first solder bumps 104 may be tin or tin alloy. When there is no direct electrical connection between the flexible circuit board 103 and the first substrate 101, various different arrangement methods may be included. In some embodiments, the flexible circuit board 103 further includes a plurality of second side surfaces located between the first functional surface and the second functional surface, a second side surface of the flexible circuit board 103, which is close to the upper surface of the first substrate 101, is suspended on the upper surface of the first substrate 101, or a second side surface of the flexible circuit board 103, which is close to the upper surface of the first substrate 101, is adhered to the upper surface of the first substrate 101, such that there is no direct electrical connection between the flexible circuit board 103 and the first substrate 101.

When the flexible circuit board 103 is directly electrically connected with the first semiconductor chips 201 in the chip stacked structure 20 and is directly electrically connected with the first substrate 101, in another embodiment, referring to FIG. 3, the implementation method thereof is: the first solder pads on the first functional surface of the flexible circuit board 103 are soldered and electrically connected with the first side solder pads 209 on the first side surfaces of the corresponding first semiconductor chips 201 in the chip stacked structure 20 through first solder bumps 104; a part of the flexible circuit board 103 is bent and extends parallel to a part of the upper surface of the first substrate 101, and the bent portion of the flexible circuit board 103 is soldered and electrically connected with the corresponding first upper solder pads on the upper surface of the first substrate 101 through connection solder balls 105.

When the flexible circuit board 103 is directly electrically connected with the first semiconductor chips 201 in the chip stacked structure 20 and is directly electrically connected with the first substrate 101, in another embodiment, referring to FIG. 4, the implementation method thereof is: the first solder pads on the first functional surface of the flexible circuit board 103 are soldered and electrically connected with the first side solder pads 209 on the first side surfaces of the corresponding first semiconductor chips 201 in the chip stacked structure 20 through the first solder bumps 104; the flexible circuit board 103 and the first substrate 101 are rigid-flex boards, and the flexible circuit board 103 is flexible, and the first substrate 101 is rigid, and the flexible circuit board 103 is partially embedded into the first substrate 101 and electrically connected with the first substrate 101, and in some embodiments, an end of the flexible circuit board 103 is embedded into the first substrate 101 and electrically connected with the first substrate 101. When the flexible circuit board 103 and the first substrate 101 are rigid-flex boards, the flexible circuit board 103 and the first substrate 101 may be manufactured together.

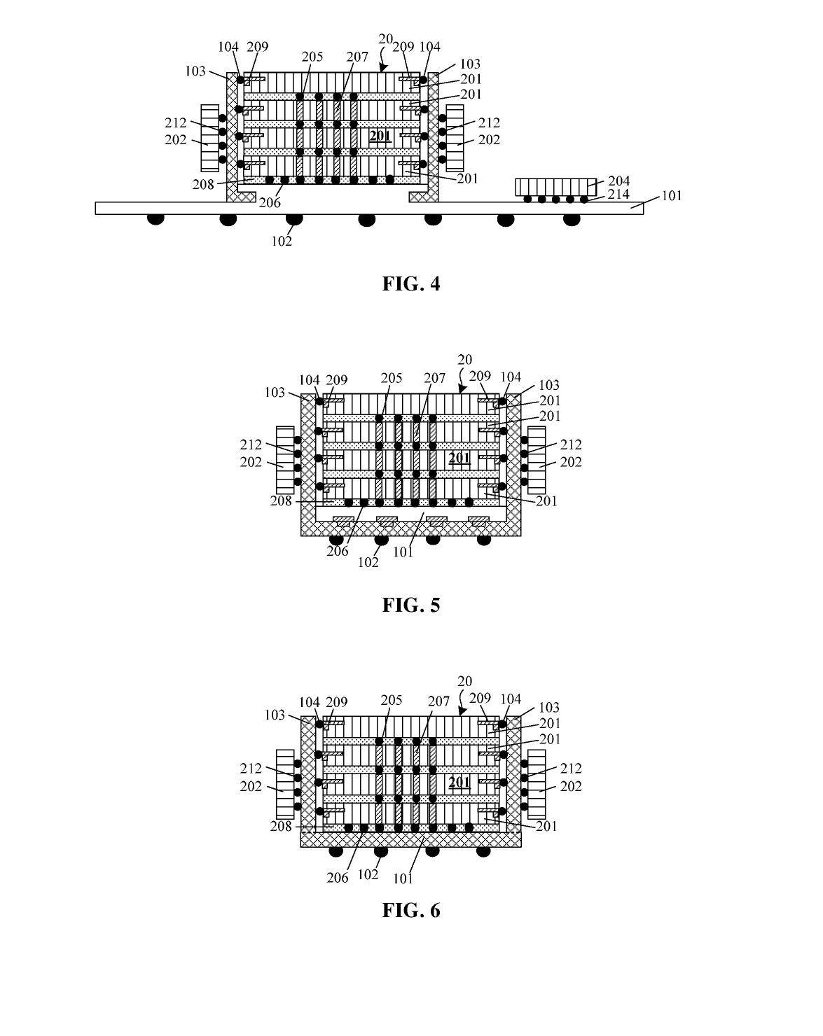

When the flexible circuit board 103 is directly electrically connected with the first semiconductor chips 201 in the chip stacked structure 20 and is directly electrically connected with the first substrate 101, in another embodiment, referring to FIG. 5, the implementation method thereof is: the first solder pads on the first functional surface of the flexible circuit board 103 are soldered and electrically connected with the first side solder pads 209 on the first side surfaces of the corresponding first semiconductor chips 201 in the chip stacked structure 20 through first solder bumps 104; the first substrate 101 further includes a plurality of side surfaces located between the upper surface and the lower surface, and the flexible circuit board 103 extends from at least one side surface of the first substrate 101 to the lower surface of the first substrate 101 and is electrically connected with the first substrate 101 from the lower surface of the first substrate 101, and in some embodiments, the flexible circuit board 103 may extend from one side surface or more side surfaces of the first substrate 101 to a part of the lower surface or the entire lower surface of the first substrate 101 and is electrically connected with the first substrate 101 from the lower surface of the first substrate 101. It should be noted that in this embodiment, the first external solder bumps 102 are formed on the second functional surface of this portion of the flexible circuit board 103 extending to a part of the lower surface or the entire lower surface of the first substrate 101, or the first external solder bumps 102 may also be formed on the lower surface of the first substrate 101 not covered by the extending flexible circuit board 103.

When the flexible circuit board 103 is directly electrically connected with the first semiconductor chips 201 in the chip stacked structure 20 and is directly electrically connected with the first substrate 101, in another embodiment, referring to FIG. 6, the implementation method thereof is: the first solder pads on the first functional surface of the flexible circuit board 103 are soldered and electrically connected with the first side solder pads 209 on the first side surfaces of the corresponding first semiconductor chips 201 in the chip stacked structure 20 through the first solder bumps 104; the first substrate 101 is also a flexible board, and the first substrate 101 and the flexible circuit board 103 are one-piece structures with electrical connections, and the flexible circuit board 103 is bent upward from at least one side of the first substrate 101. In some embodiments, the first substrate 101 includes four sides, and the flexible circuit board 103 is bent upward from one of the sides of the first substrate 101, or the flexible circuit board 103 is bent upward from two of the sides of the first substrate 101, or the flexible circuit board 103 is bent upward from three of the sides of the first substrate 101, or the flexible circuit board 103 is bent upward from four of the sides of the first substrate 101.

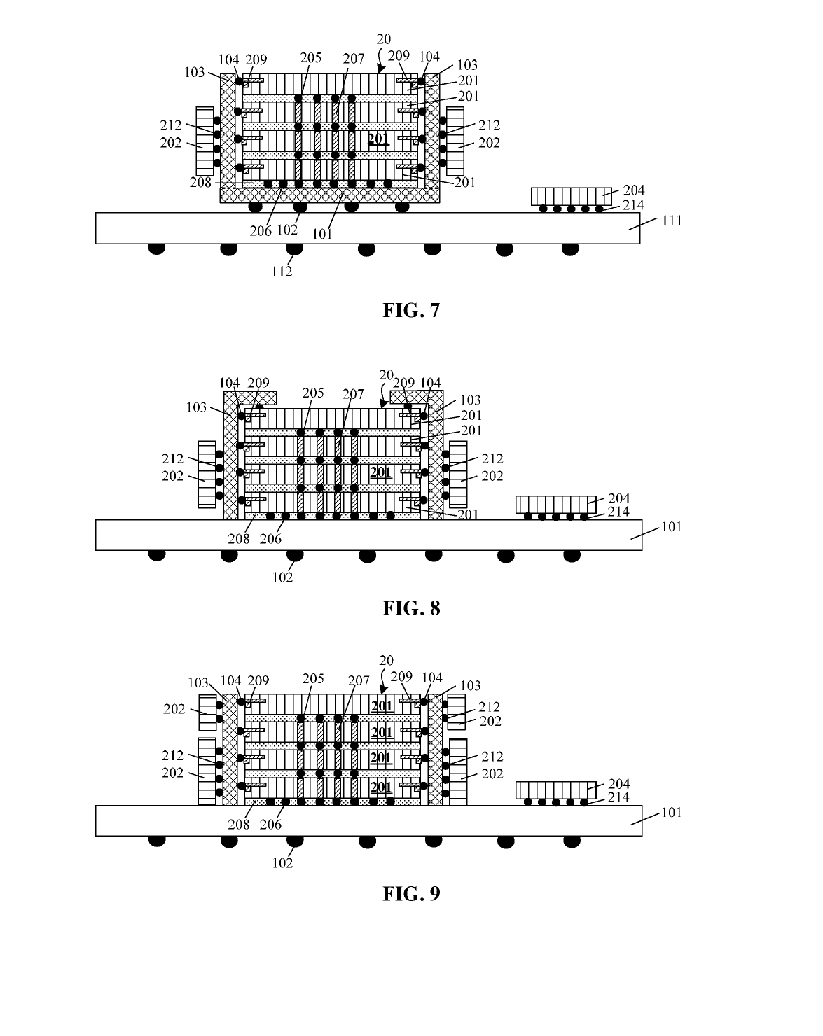

In one embodiment, when the first substrate 101 is also a flexible board, and the first substrate 101 and the flexible circuit board 103 are one-piece structures with electrical connections, referring to FIG. 7, the first solder pads on the first functional surface of the flexible circuit board 103 are soldered and electrically connected with the first side solder pads 209 on the first side surface of the corresponding first semiconductor chips 201 in the chip stacked structure 20 through first solder bumps 104; the stacked package structure further includes: a second substrate 111, and the second substrate 111 has in it third lines, and the upper surface of the second substrate 111 has second upper solder pads, and the lower surface of the second substrate 111 has second lower solder pads, and the second upper solder pads and the second lower solder pads are electrically connected with the third lines; the first substrate 101 is located on the second substrate 111, and the first external solder bumps 102 on the lower surface of the first substrate 101 are soldered together with the corresponding second upper solder pads on the upper surface of the second substrate 111; the surfaces of the second lower solder pads on the lower surface of the second substrate 111 include protruding second external solder bumps 112.

When the flexible circuit board 103 is not directly electrically connected with the first semiconductor chips 201 in the chip stacked structure 20 but is directly electrically connected with the first substrate 101, in one embodiment, referring again to FIGS. 12 and 13, FIG. 13 is a cross-sectional structural schematic diagram of the stacked package structure obtained along cutting line AA1 in FIG. 12, the implementation method thereof is: the first side surfaces of the first semiconductor chips 201 in the chip stacked structure 20 do not include first side solder pads; the flexible circuit board 103 includes opposed first functional surface and second functional surface, and a plurality of second side surfaces located between the first functional surface and the second functional surface, and the first functional surface of the flexible circuit board 103 is adhered to the side surface of the chip stacked structure 20, and in some embodiments, the first functional surface of the flexible circuit board 103 is adhered to the side surface of the chip stacked structure 20 through an adhesive layer 106, and the adhesive layer 106 may be a resin film or a resin adhesive with stickiness. A second side of the flexible circuit board 103 close to the upper surface of the first substrate 101 has third side pads (i.e., pads on the second side of the flexible circuit board 103 facing the first substrate 101), and the third side pads are directly electrically connected with the corresponding first upper pads (i.e., pads on the upper surface of the first substrate 101 facing the flexible circuit board 103) on the upper surface of the first substrate 101 through solder bumps 110.

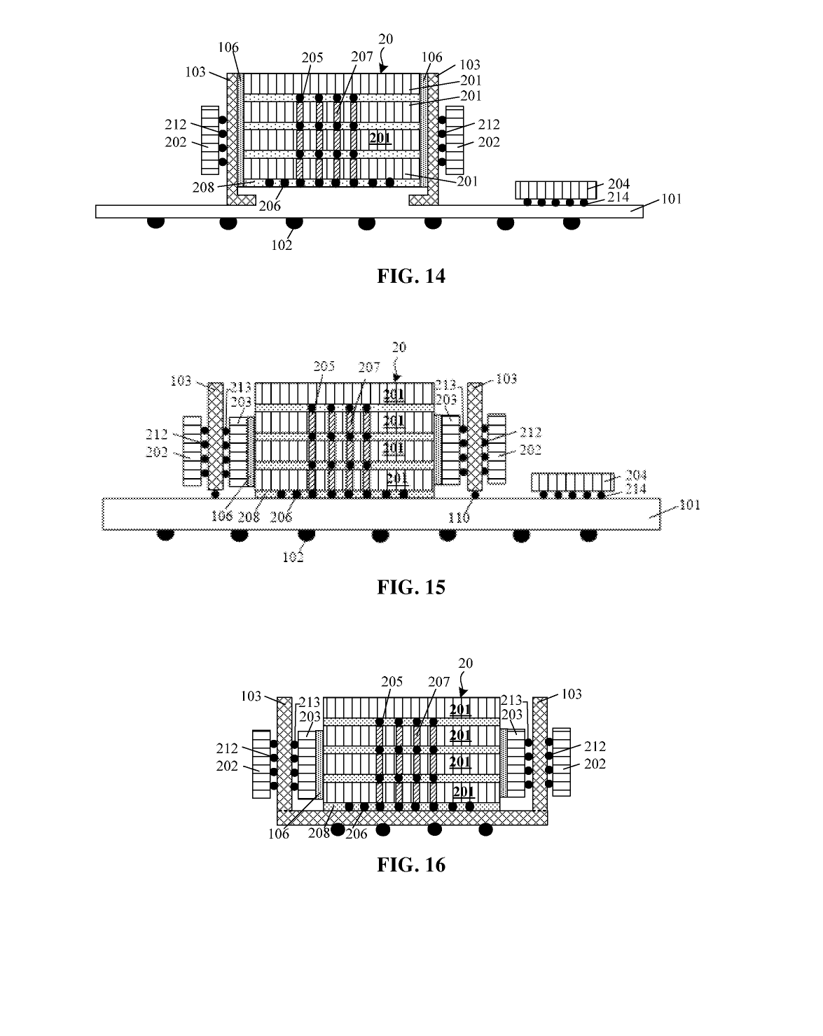

When the flexible circuit board 103 is not directly electrically connected with the first semiconductor chips 201 in the chip stacked structure 20 but is directly electrically connected with the first substrate 101, in another embodiment, referring to FIG. 14, the implementation method thereof is: the first functional surface of the flexible circuit board 103 is adhered to the side surface of the chip stacked structure 20 through an adhesive layer 106. The flexible circuit board 103 and the first substrate 101 are rigid-flex boards, and the flexible circuit board 103 is flexible and the first substrate 101 is rigid, and the flexible circuit board 103 is partially embedded into the first substrate 101 and electrically connected with the first substrate 101, and in some embodiments, an end of the flexible circuit board 103 is embedded into the first substrate 101 and electrically connected with the first substrate 101. When the flexible circuit board 103 and the first substrate 101 are rigid-flex boards, the flexible circuit board 103 and the first substrate 101 may be manufactured together.

In another embodiment, the first functional surface of the flexible circuit board 103 is adhered to the side surface of the chip stacked structure 20 through an adhesive layer 106, such that there is no direct electrical connection exists between the flexible circuit board 103 and the first semiconductor chips 201 in the chip stacked structure 20, while the methods of direct electrical connection between the flexible circuit board 103 and the first substrate 101, in addition to the implementation methods shown in the aforementioned FIGS. 13 and 14, may also use the implementation methods shown in FIGS. 3, 5, 6, or 7 in the aforementioned embodiments.

When the flexible circuit board 103 is not directly electrically connected with the first semiconductor chips 201 in the chip stacked structure 20, but is directly electrically connected with the first substrate 101, in another embodiment, referring to FIG. 15, the implementation method thereof is: the first functional surface (i.e., a surface facing the third semiconductor chips 203) of the flexible circuit board 103 further includes a plurality of discrete first solder pads (i.e., pads on the flexible circuit board 103 facing the third semiconductor chips 203), and the first solder pads are electrically connected with the second lines in the flexible circuit board 103 (i.e., lines formed on the first functional surface of the flexible circuit board 103 or in the flexible circuit board 103); the stacked package structure further includes the third semiconductor chips 203, the third semiconductor chips 203 are mounted on the first functional surface of the flexible circuit board 103 and electrically connected with corresponding first solder pads on the first functional surface through third solder bumps 213; the third semiconductor chips 203 are adhered to the side surface of the chip stacked structure 20 through an adhesive layer 106, i.e., the first functional surface of the flexible circuit board 103 is adhered to or mounted on the side surface of the chip stacked structure 20 through the third semiconductor chips 203 and the adhesive layer 106, and the flexible circuit board 103 has no direct electrical connection with the first semiconductor chips 201 in the chip stacked structure 20, while the flexible circuit board 103 has a direct electrical connection with the first substrate 101, the implementation method may be: the third side solder pads (i.e., pads on second side surface of the flexible circuit board 103 facing the first substrate 101) on the second side surface of the flexible circuit board 103 close to the upper surface of the first substrate 101 are directly electrically connected with the corresponding first upper solder pads (i.e., pads on the first substrate 101 facing the flexible circuit board 103) on the upper surface of the first substrate 101 through solder bumps 110, or it is achieved through the method that the first substrate 101 shown in FIG. 16 is also a flexible board and the first substrate 101 and the flexible circuit board 103 are one-piece structures with an electrical connection, or it is achieved through other specific connection method of the flexible circuit board 103 with the first substrate 101 as described in any one of the aforementioned embodiments.

In one embodiment, referring to FIG. 8, in the stacked package structure, a part of the flexible circuit board 103 is bent and extends parallel to the second surfaces of the first semiconductor chips 201 of the topmost layer in the chip stacked structure 20, and is electrically connected with a part of the second external terminals on the second surfaces of the first semiconductor chips 201 of the topmost layer through solder bumps. This further improves the connection port of the flexible circuit board 103 with the chip stacked structure 20, which is conductive to increasing bandwidth.

In one embodiment, in the stacked package structure, the number of the second semiconductor chips 202 is one or more; when the number of the second semiconductor chips 202 is multiple, referring to FIG. 11, a plurality of second semiconductor chips 202 are stacked in sequence along a direction parallel to the upper surface of the first substrate 101 on the second functional surface of the flexible circuit board 103, or referring to FIG. 9, a plurality of second semiconductor chips 202 are mounted at different positions on the second functional surface of the flexible circuit board 103. This further increases the number of chips packaged on a given area in the stacked package structure.

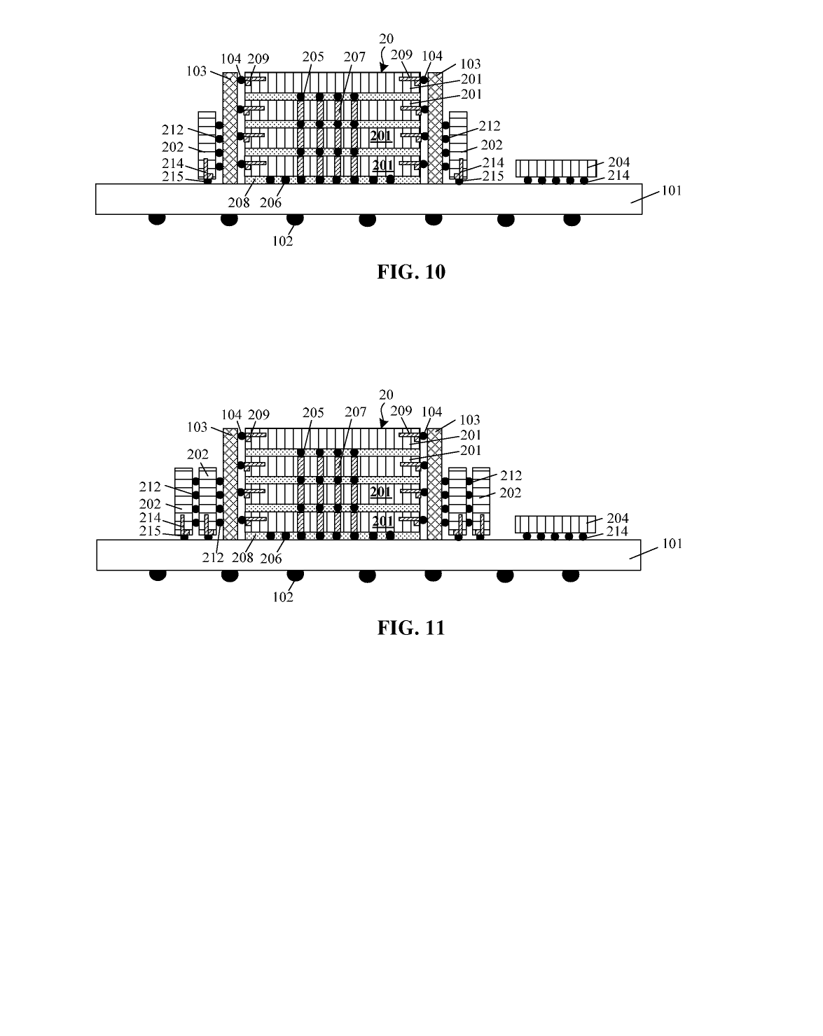

In one embodiment, referring to FIG. 10 or FIG. 11, the second semiconductor chips 202 includes opposed third surface and fourth surface as well as a plurality of side surfaces between the third surface and the fourth surface, and the third surface has third external terminals (i.e., terminals, such as solder bumps or through-via connection structures, on the third surface of the second semiconductor chips 202 facing the flexible circuit board 103), and the third external terminals on the third surfaces of the second semiconductor chips 202 are electrically connected with the corresponding second solder pads (i.e., pads on the second functional surface of the flexible circuit board 103 facing the second semiconductor chips 202) on the second functional surface of the flexible circuit board 103 through the second solder bumps 212; the side surface of the second semiconductor chips 202 close to the upper surface of the first substrate 101 has second side solder pads 214, and the second side solder pads 214 are soldered with the corresponding first upper solder pads (i.e., pads on the upper surface of the first substrate 101 facing the second semiconductor chips 202) on the upper surface of the first substrate 101 through fourth solder bumps 215.

In one embodiment, the stacked package structure further includes other semiconductor chips or devices 204, and the other semiconductor chips or devices 204 are mounted on the upper surface of the first substrate 101 (referring to FIGS. 2, 3, 4, 13, 14, or 15) or the upper surface of the second substrate 111 (referring to FIG. 7) on a side of the chip stacked structure 20. The other semiconductor chips or devices 204 may be electrically connected with the chip stacked structure 20 through a part of the first lines in the first substrate 101 to communicate or exchange or transmit data, for example, they are electrically connected with a first semiconductor chip of the bottom layer in the chip stacked structure 20. In some embodiments, the other semiconductor chips or devices 204 may also be electrically connected with the second semiconductor chips 202 through a part of the first lines in the first substrate 101 and a part of the second lines in the flexible circuit board 103 to communicate or exchange or transmit data. In some embodiments, the other semiconductor chips or devices 204 may also be electrically connected with both the chip stacked structure 20 and the second semiconductor chips 202 through a part of the first lines in the first substrate 101 and a part of the second lines in the flexible circuit board 103 to communicate or exchange or transmit data.

Another embodiment of the present disclosure also provides a method for forming a stacked package structure, referring to FIGS. 1 and 2 or FIGS. 12 and 13, which includes: providing a first substrate 101, the first substrate 101 includes opposed upper surface and lower surface; forming a chip stacked structure 20 on the upper surface of the first substrate 101, the chip stacked structure 20 includes a plurality of first semiconductor chips 201 stacked in sequence along a direction perpendicular to the upper surface of the first substrate 101, and the chip stacked structure 20 is electrically connected with the first substrate 101; and mounting a flexible circuit board 103 on at least one side surface of the chip stacked structure 20, the flexible circuit board 103 includes opposed first functional surface and second functional surface, and the first functional surface is close to the corresponding side surface of the chip stacked structure 20 and is perpendicular to the upper surface of the first substrate 101, the second functional surface is away from the corresponding side surface of the chip stacked structure 20 and is perpendicular to the upper surface of the first substrate 101, and second semiconductor chips 202 electrically connected with the flexible circuit board 103 are mounted on the second functional surface of the flexible circuit board 103.

In one embodiment, each first semiconductor chip 201 in the chip stacked structure 20 includes opposed first surface and second surface, and a first side surface located between the first surface and the second surface, and the first semiconductor chips 201 include in them integrated circuits, and the first surface has a plurality of discrete first external terminals, and the second surface has a plurality of discrete second external terminals, and the first external terminals and second external terminals are electrically connected with the integrated circuits; when a plurality of first semiconductor chips 201 are stacked in sequence along a direction perpendicular to the upper surface of the first substrate 101, the first surfaces of the first semiconductor chips 201 in the upper-layer (i.e., the upper-layer first semiconductor chip among the first semiconductor chips 201) are stacked, facing downward, on the second surfaces of the first semiconductor chips 201 in the lower-layer (i.e., the lower-layer first semiconductor chip among the first semiconductor chips 201), and the first external terminals on the first surfaces of the first semiconductor chips 201 in the upper-layer are electrically connected with the second external terminals on the second surfaces of the first semiconductor chips 201 in the lower-layer; the first substrate 101 has in it first lines, and the upper surface of the first substrate 101 has a plurality of discrete first upper solder pads, and the lower surface of the first substrate 101 has a plurality of discrete first lower solder pads, the first upper solder pads and first lower solder pads are electrically connected with the first lines, the first external terminals on the first surfaces of the first semiconductor chips 201 of the bottommost layer are electrically connected with the corresponding first upper solder pads on the upper surface of the first substrate 101.

In one embodiment, referring to FIGS. 1 and 2, the first side surfaces of the first semiconductor chips 201 include first side solder pads 209; the flexible circuit board 103 has in it second lines, and the first functional surface of the flexible circuit board 103 has a plurality of discrete first solder pads, and the second functional surface of the flexible circuit board 103 has a plurality of discrete second solder pads, and the first solder pads and the second solder pads are electrically connected with the second lines; the second semiconductor chips are electrically connected with the corresponding second solder pads on the second functional surface of the flexible circuit board 103; the first solder pads on the first functional surface of the flexible circuit board 103 are electrically connected with the first side solder pads 209 on the first side surface of the corresponding first semiconductor chips 201 in the chip stacked structure.

In one embodiment, the flexible circuit board 103 is mounted on at least one side surface of the chip stacked structure 20, and the first solder pads on the first functional surface of the flexible circuit board 103 being electrically connected with the first side solder pads 209 on the first side surface of the corresponding first semiconductor chips 201 in the chip stacked structure includes: the first solder pads on the first functional surface of the flexible circuit board 103 are soldered together with and electrically connected with the first side solder pads 209 on the first side surface of the corresponding first semiconductor chips 201 in the chip stacked structure through first solder bumps 104.

In one embodiment, the second semiconductor chips 202 being electrically connected with the corresponding second solder pads on the second functional surface of the flexible circuit board 103 includes: the second semiconductor chips 202 are electrically connected with the corresponding second solder pads on the second functional surface of the flexible circuit board 103 through second solder bumps 212.

In one embodiment, referring to FIGS. 12 and 13, the first side surfaces of the first semiconductor chips 201 do not include first side solder pads 209; the flexible circuit board 103 has in it second lines, and the first functional surface of the flexible circuit board 103 further has a plurality of discrete first solder pads, and the second functional surface of the flexible circuit board 103 has a plurality of discrete second solder pads, and the first solder pads and the second solder pads are electrically connected with the second lines; the second semiconductor chips 202 are electrically connected with the corresponding second solder pads; and the flexible circuit board 103 being mounted on at least one side surface of the chip stacked structure 20 includes: the first functional surface of the flexible circuit board 103 is adhered to the side surface of the chip stacked structure 20.

In one embodiment, referring to FIG. 12, the first functional surface of the flexible circuit board 103 being adhered to the side surface of the chip stacked structure 20 includes: the first functional surface of the flexible circuit board 103 is adhered to the side surface of the chip stacked structure 20 through an adhesive layer 106.

In one embodiment, referring to FIG. 15, the stacked package structure further includes third semiconductor chips 203, and the third semiconductor chips 203 are mounted on the first functional surface of the flexible circuit board 103 and electrically connected with corresponding first solder pads on the first functional surface through third solder bumps 213; and the first functional surface of the flexible circuit board 103 being adhered to the side surface of the chip stacked structure 20 includes: the third semiconductor chips 203 mounted on the first functional surface of the flexible circuit board 103 are adhered to the side surface of the chip stacked structure through an adhesive layer 106.

In one embodiment, the flexible circuit board 103 is electrically connected with the first substrate 101.

It should be noted that the same or similar parts in the embodiments of the aforementioned method for forming the stacked package structure and in the embodiments of the aforementioned stacked package structure will not be repeated in the embodiment portions of the method for forming the stacked package structure, and for details, reference may be made to the definitions or descriptions of the corresponding sections in the embodiments of the aforementioned stacked package structure.

Although the present disclosure has been disclosed above with embodiments, they are not intended to limit the present disclosure; any person skilled in the art may make possible changes and modifications to the technical solutions disclosed herein without departing from the spirit and scope of the present disclosure, therefore, any simple modifications, equivalent changes, and refinements made to the above embodiments based on the technical essence of the present disclosure without departing from the content of the technical solutions of the present disclosure, shall fall within the scope of protection of the technical solutions of the present disclosure.

What is claimed is:

1. A stacked package structure, comprising:
a first substrate comprising an upper surface and a lower surface opposite to the upper surface;
a chip stacked structure located on the upper surface of the first substrate, wherein the chip stacked structure comprises first semiconductor chips stacked in sequence along a direction perpendicular to the upper surface of the first substrate, and the chip stacked structure is electrically connected to the first substrate; and
a flexible circuit board mounted on at least one side surface of the chip stacked structure,
wherein the flexible circuit board comprises a first functional surface and a second functional surface opposite to the first functional surface;
the first functional surface is close to the corresponding side surface of the chip stacked structure and perpendicular to the upper surface of the first substrate;
the second functional surface is away from the corresponding side surface of the chip stacked structure and perpendicular to the upper surface of the first substrate; and
second semiconductor chips, electrically connected to the flexible circuit board, are mounted on the second functional surface of the flexible circuit board.

2. The stacked package structure according to claim 1, wherein:
each of the first semiconductor chips in the chip stacked structure comprises a first surface and a second surface opposite to the first surface, wherein a first side surface located between the first surface and the second surface, and the first semiconductor chips comprise integrated circuits;
the first surface comprises a plurality of discrete first external terminals, and the second surface comprises a plurality of discrete second external terminals, wherein the first external terminals and the second external terminals are electrically connected to the integrated circuits;
when the first semiconductor chips are stacked in sequence along the direction perpendicular to the upper surface of the first substrate, the first surface of an upper-layer first semiconductor chip is stacked facing downward on the second surface of a lower-layer first semiconductor chip, and the first external terminals on the first surface of the upper-layer first semiconductor chip are electrically connected to the second external terminals on the second surface of the lower-layer first semiconductor chip;
the first substrate comprises first lines, and the upper surface of the first substrate comprises a plurality of discrete first upper solder pads, and the lower surface of the first substrate comprises a plurality of discrete first lower solder pads, the first upper solder pads and the first lower solder pads are electrically connected to the first lines; and
the first external terminals on the first surface of a bottommost first semiconductor chip are electrically connected to the corresponding first upper solder pads on the upper surface of the first substrate.

3. The stacked package structure according to claim 2, wherein:
the first side surfaces of the first semiconductor chips comprise first side solder pads;
the flexible circuit board comprises second lines, the first functional surface of the flexible circuit board comprises a plurality of discrete first solder pads, the second functional surface of the flexible circuit board comprises a plurality of discrete second solder pads, and the first solder pads and the second solder pads are electrically connected to the second lines;
the second semiconductor chips are electrically connected to the corresponding second solder pads on the second functional surface of the flexible circuit board; and
the first solder pads on the first functional surface of the flexible circuit board are electrically connected to the first side solder pads on the first side surface of the corresponding first semiconductor chip in the chip stacked structure.

4. The stacked package structure according to claim 3, wherein:
the flexible circuit board is mounted on at least one side surface of the chip stacked structure, wherein the first solder pads on the first functional surface of the flexible circuit board are electrically connected to the first side solder pads on the first side surface of the corresponding first semiconductor chip in the chip stacked structure comprises:
the first solder pads on the first functional surface of the flexible circuit board are soldered together with and electrically connected to the first side solder pads on the first side surface of the corresponding first semiconductor chip in the chip stacked structure through first solder bumps; and
the second semiconductor chips are electrically connected to the corresponding second solder pads on the second functional surface of the flexible circuit board comprises: the second semiconductor chips are electrically connected to the corresponding second solder pads on the second functional surface of the flexible circuit board through second solder bumps.

5. The stacked package structure according to claim 3, wherein:
the flexible circuit board further comprises a plurality of second side surfaces located between the first functional surface and the second functional surface; and
a second side surface of the flexible circuit board close to the upper surface of the first substrate is suspended above the upper surface of the first substrate or adhered to the upper surface of the first substrate.

6. The stacked package structure according to claim 2, wherein:
the first side surfaces of the first semiconductor chips comprise no first side solder pads;
the flexible circuit board comprises second lines;
the first functional surface of the flexible circuit board further comprises a plurality of discrete first solder pads;
the second functional surface of the flexible circuit board comprises a plurality of discrete second solder pads;
the first solder pads and the second solder pads are electrically connected to the second lines;
the second semiconductor chips are electrically connected to the corresponding second solder pads; and
the first functional surface of the flexible circuit board is adhered to the side surface of the chip stacked structure.

7. The stacked package structure according to claim 6, wherein the flexible circuit board is mounted on at least one side surface of the chip stacked structure, and the first functional surface of the flexible circuit board being mounted on the side surface of the chip stacked structure comprises: the first functional surface of the flexible circuit board is adhered to the side surface of the chip stacked structure through an adhesive layer.

8. The stacked package structure according to claim 6, wherein:
the stacked package structure further comprises third semiconductor chips, wherein the third semiconductor chips are mounted on the first functional surface of the flexible circuit board and electrically connected to corresponding first solder pads on the first functional surface through third solder bumps; and
the flexible circuit board being mounted on at least one side surface of the chip stacked structure, and the first functional surface of the flexible circuit board adhered to the side surface of the chip stacked structure comprises: the third semiconductor chips mounted on the first functional surface of the flexible circuit board are adhered to the side surface of the chip stacked structure through an adhesive layer.

9. The stacked package structure according to claim 3, wherein the flexible circuit board is electrically connected to the first substrate.

10. The stacked package structure according to claim 9, wherein the flexible circuit board being electrically connected to the first substrate comprises: a part of the flexible circuit board is bent and extends parallel to a part of the upper surface of the first substrate, and a bent portion of the flexible circuit board is soldered and electrically connected to the corresponding first upper solder pads on the upper surface of the first substrate through connection solder balls.

11. The stacked package structure according to claim 9, wherein the flexible circuit board being electrically connected to the first substrate comprises: the flexible circuit board and the first substrate are rigid-flex boards, the flexible circuit board is flexible and the first substrate is rigid, and the flexible circuit board is partially embedded into the first substrate and electrically connected to the first substrate.

12. The stacked package structure according to claim 9, wherein the flexible circuit board being electrically connected to the first substrate comprises: the first substrate further comprises a plurality of side surfaces located between the upper surface and the lower surface, the flexible circuit board extends from at least one side surface of the first substrate to the lower surface of the first substrate and is electrically connected to the first substrate from the lower surface of the first substrate.

13. The stacked package structure according to claim 9, wherein the flexible circuit board being electrically connected to the first substrate comprises:
the first substrate is also a flexible board;
the first substrate and the flexible circuit board are a one-piece structure with an electrical connection; and
the flexible circuit board is bent upward from at least one side of the first substrate.

14. The stacked package structure according to claim 13, wherein:
surfaces of the first lower solder pads on the lower surface of the first substrate comprise protruding first external solder bumps;
the stacked package structure further comprises: a second substrate comprising third lines,
an upper surface of the second substrate comprises second upper solder pads,
a lower surface of the second substrate comprises second lower solder pads,
the second upper solder pads and the second lower solder pads are electrically connected to the third lines;
the first substrate is located on the second substrate, and the first external solder bumps on the lower surface of the first substrate are soldered together with the corresponding second upper solder pads on the upper surface of the second substrate; and
surfaces of the second lower solder pads on the lower surface of the second substrate comprise protruding second external solder bumps.

15. The stacked package structure according to claim 3, wherein a part of the flexible circuit board is bent and extends parallel to the second surface of a topmost first semiconductor chip in the chip stacked structure, and is electrically connected to a part of the second external terminals on the second surface of the topmost first semiconductor chip.

16. The stacked package structure according to claim 3, wherein the flexible circuit board is located on the upper surface of the first substrate on one or more sides of the chip stacked structure.

17. The stacked package structure according to claim 4, wherein a number of the second semiconductor chips is one or more; and
when the number of the second semiconductor chips is multiple, the second semiconductor chips are stacked in sequence along a direction parallel to the upper surface of the first substrate on the second functional surface of the flexible circuit board, or the second semiconductor chips are all mounted at different positions on the second functional surface of the flexible circuit board.

18. The stacked package structure according to claim 17, wherein:
the second semiconductor chips comprise a third surface, a fourth surface opposite to the third surface, and a plurality of side surfaces between the third surface and the fourth surface;
the third surface comprises third external terminals, and the third external terminals on the third surface of the second semiconductor chip are electrically connected to the corresponding second solder pads on the second functional surface of the flexible circuit board through second solder bumps; and
a side surface of the second semiconductor chips close to the upper surface of the first substrate comprises second side solder pads, and the second side solder pads are soldered together with the corresponding first upper solder pads on the upper surface of the first substrate through fourth solder bumps.

19. A method for forming a stacked package structure, comprising:
providing a first substrate, the first substrate comprises an upper surface and a lower surface opposite to the upper surface;
forming a chip stacked structure on the upper surface of the first substrate, wherein the chip stacked structure comprises first semiconductor chips stacked in sequence along a direction perpendicular to the upper surface of the first substrate, and the chip stacked structure is electrically connected to the first substrate; and
mounting a flexible circuit board on at least one side surface of the chip stacked structure, wherein:
the flexible circuit board comprises a first functional surface and a second functional surface opposite to the first functional surface;
the first functional surface is close to the corresponding side surface of the chip stacked structure and is perpendicular to the upper surface of the first substrate;
the second functional surface is away from the corresponding side surface of the chip stacked structure and is perpendicular to the upper surface of the first substrate; and
second semiconductor chips electrically connected to the flexible circuit board are mounted on the second functional surface of the flexible circuit board.

20. The method for forming the stacked package structure according to claim 19, wherein:
each of the first semiconductor chips in the chip stacked structure comprises a first surface, a second surface opposite to the first surface, and a first side surface located between the first surface and the second surface;
the first semiconductor chips comprise integrated circuits, the first surface comprises a plurality of discrete first external terminals, the second surface comprises a plurality of discrete second external terminals, and the first external terminals and the second external terminals are electrically connected to the integrated circuits;
when the first semiconductor chips are stacked in sequence along a direction perpendicular to the upper surface of the first substrate, the first surface of an upper-layer first semiconductor chip is stacked facing downward on the second surface of a lower-layer first semiconductor chip, and the first external terminals on the first surface of the upper-layer first semiconductor chip are electrically connected to the second external terminals on the second surface of the lower-layer first semiconductor chip;
the first substrate comprises first lines, the upper surface of the first substrate comprises a plurality of discrete first upper solder pads, and the lower surface of the first substrate comprises a plurality of discrete first lower solder pads; and
the first upper solder pads and the first lower solder pads are electrically connected to the first lines, the first external terminals on the first surface of a bottommost first semiconductor chip are electrically connected to the corresponding first upper solder pads on the upper surface of the first substrate.
